(19) United States
(12) Patent Application Publication
(10) Pub. No.: US 2017/0094800 A1
(43) Pub. Date: Mar. 30, 2017

(54) METHOD AND ARRANGEMENT FOR PROVIDING ELECTRICAL CONNECTION TO IN-MOLD ELECTRONICS

(71) Applicant: TactoTek Oy, Kempele (FI)

(72) Inventors: Antti KERANEN, Oulu (FI); Mikko HEIKKINEN, Oulu (FI); Pasi RAAPPANA, Kempele (FI); Jarmo SAASKI, Kempele (FI)

(21) Appl. No.: 15/279,080

(22) Filed: Sep. 28, 2016

Related U.S. Application Data
(60) Provisional application No. 62/233,755, filed on Sep. 28, 2015.

(51) Int. Cl. H05K 1/18; H05K 1/11; H05K 1/16; H05K 3/46; H05K 3/12; H05K 3/28; H05K 3/00; H05K 1/02; H05K 3/40

(52) U.S. Cl. CPC H05K 1/189; H05K 1/0269; H05K 1/111; H05K 1/118; H05K 1/16; H05K 1/028; H05K 3/4092; H05K 3/12; H05K 3/28; H05K 3/0044; H05K 3/46; H05K 2201/0129; H05K 2203/0228

(57) ABSTRACT

A multilayer structure includes a flexible substrate film having a first side and opposite second side, a number of conductive traces, optionally defining contact pads and/or conductors, printed on the first side for establishing a desired predetermined circuit design, a plastic layer molded onto the first side so as to enclose the circuit between the plastic layer and the first side, and a connector in a form of a flexible flap for providing external electrical connection to the embedded circuit from the second, opposite side, the connector defined by a portion of the substrate film accommodating at least part of one or more of the printed conductive traces and cut partially loose from the surrounding substrate material to establish the flap, whose loose end is bendable away from the molded plastic layer to facilitate establishment of the electrical connection with external element, wire or connector, via the associated gap.

### FIELD OF THE INVENTION

Generally the present invention relates to electronics, associated devices, structures and methods of manufacture. In particular, however not exclusively, the present invention concerns provision of external electrical connection to the internals of a structure containing a film layer and adjacent molded plastics layer integrated together.

### BACKGROUND

Generally there exists a variety of different stacked assemblies and structures in the context of electronics and electronic products.

The motivation behind the integration of electronics and related products may be as diverse as the related use contexts. Relatively often size savings, weight savings, cost savings, or just efficient integration of components is sought for when the resulting solution ultimately exhibits a multilayer nature. In turn, the associated use scenarios may relate to product packages or food casings, visual design of device housings, wearable electronics, personal electronic devices, displays, detectors or sensors, vehicle interiors, antennae, labels, vehicle electronics, etc.

Electronics such as electronic components, ICs (integrated circuit), and conductors, may be generally provided onto a substrate element by a plurality of different techniques. For example, ready-made electronics such as various surface mount devices (SMD) may be mounted on a substrate surface that ultimately forms an inner or outer interface layer of a multilayer structure. Additionally, technologies falling under the term “printed electronics” may be applied to actually produce electronics directly and additively to the associated substrate. The term “printed” refers in this context to various printing techniques capable of producing electronics/electrical elements from the printed matter, including but not limited to screen printing, flexography, and inkjet printing, through substantially additive printing process. The used substrates may be flexible and printed materials organic, which is however, not necessarily always the case.

When a multilayer structure is loaded with various electronics, related power, data and/or control connections may have to be provided thereto, which typically requires provision of electrical connectors and related wiring even though also wireless connections may be occasionally applicable.

Commonly, the wired electrical connections between the environment and the embedded electronics of a stacked multilayer structure are provided at a side edge of the structure so that the necessary external wiring is brought into contact with a connector or other contact element that is located, and potentially protrudes out from the substrate and related overall structure, at the periphery thereof.

However, in many use scenarios such configuration of connectors and external wiring is sub-optimum, because it puts additional constraints on the dimensioning and positioning of related host structures and components, not forgetting the features and manufacturing of the multilayer structure itself.

### SUMMARY

The objective of the present invention is to at least alleviate one or more of the above drawbacks associated with the existing solutions in the context of integral multilayer structures and electronics embedded therein.

The objective is achieved with various embodiments of a multilayer structure and related method of manufacture in accordance with the present invention.

According to one embodiment of the present invention, a multilayer structure for an electronic device comprises

a preferably flexible substrate film capable of accommodating electronics, such as conductive traces and optionally electronic components such as SMDs (surface-mount device), on a first side thereof, said film having a first side and a second side,

a number of conductive traces, such as contact pads and/or conductors, preferably printed on the first side of the substrate film by printed electronics technology for establishing a desired predetermined circuit design,

a plastic layer molded onto the first side of the substrate so as to enclose the circuit between the plastic layer and the first side of the substrate film, and

a connector in a form of a preferably flexible flap for providing external electrical connection to the embedded circuit from the second, opposite side of the substrate,

the connector being defined by a portion of the substrate film (optionally excluding the periphery of the film thus being located in the more central region) preferably accommodating at least part of one or more of the conductive traces, optionally also provided with material non-adherent to the molded plastic layer, said portion being cut partially loose from the surrounding substrate material so as to establish the flap, the loose end of which is bendable away from the molded plastic layer to facilitate the establishment of said electrical connection with an external element, such as a wire or connector, via the associated gap.

Depending on the material of the substrate and materials/elements attached thereon (such as printing material for traces and/or other elements), the flap may be relatively rigid or flexible (bend easily). In the case of a stiffer material, the flap may be bent away from the substrate by a fold at a contact area of the flap and the rest of the substrate. The fold may both control (to prevent e.g. ruptures) and facilitate opening the flap from the original closed position, or respectively help closing the flap.

The first side and thus the associated first surface of the substrate has been at least partially, having regard to the related surface area, overmolded by plastic, preferably and typically thermoplastic, material. Optionally, several overmolding-applicable materials may be utilized to establish one or more molded layers, e.g. adjacent layers lying side-to-side on the first side of the substrate and/or forming a stack of multiple superposed layers thereon.

Optionally, a further, second film is provided on the other side of the molded layer. The second film, which may act as a substrate for graphics and/or electronics, such as electronic components and/or traces, therefore faces the molded layer from a direction opposite to the primary, or first, substrate film. The second film may have been positioned, i.e. inserted, in a mold together with the first film enabling plastic material to be injected between them. Alternatively, the second film may have been laminated onto the molded layer by feasible lamination technology using e.g. adhesive, elevated temperature and/or pressure based bonding.

In some embodiments, the (thermo)plastic material used to establish the molded layer comprises optically substantially opaque, transparent or translucent material enabling e.g. visible light to pass through it with negligible loss. The sufficient transmittance at desired wavelengths may be about 85%, 90% or 95% or higher, for example. Possible further molded (thermo)plastic material may be substantially opaque or translucent. In some embodiments, the further material may be transparent.

In a further, either supplementary or alternative, embodiment one or more of the included films may at least partially be optically substantially opaque or at least translucent having regard to predefined wavelengths e.g. in visible spectrum. The film may have been initially provided with visually distinguishable, decorative/aesthetic and/or informative, features such as graphical pattern and/or color thereon or therein. The features may have been provided on the same side of the film with the electronics so that they have been also sealed by the plastic material(s) through the associated overmolding procedure. Accordingly, IML (in-mold labeling)/IMD (in-mold decoration) technique is applicable. The film(s) may be at least partially, i.e. at least in places, optically transparent or translucent to radiation such as visible light emitted by the electronics thereon. The transmittance may be about 85%, 90%, 95% or higher, for example.

According to one other embodiment, a method for manufacturing a multilayer structure for an electronic device, comprises

obtaining a substrate film for accommodating electronics,

providing, preferably by printing, a number of conductive traces, and optionally electronic components, on a first side of the substrate film to establish a predetermined circuit design,

preferably providing a separator material substantially non-adherent to thermoplastic material to be molded on the first side of the substrate, wherein the separator material is advantageously provided to a predefined location of a connector flap to be formed on the first side,

molding the thermoplastic material on said first side of the substrate film to substantially seal the circuit between the plastic layer and the first side of the substrate film,

cutting, from the substrate film, optionally excluding the periphery of the film, a partially loose flap portion comprising conductive region facing the molded material and preferably accommodating at least part of one or more of the traces, and

preferably bending the loose connector flap portion away from the molded plastic layer and the level of the remaining substrate film to enable an external element, such as a wire or a connector, to physically and electrically contact the conductive region from a second, opposite side of the substrate film via the established gap.

The order of the method items may be determined case-specifically in each embodiment. For example, the cutting phase may take place after the molding phase and/or prior to molding phase. Prior to molding, cutting is fully feasible as long as care is taken that the basically up-front established connector flap remains closed and thus sealed well enough during the molding so that the molded layer does not manage to protrude and escape to the second side of the substrate (if not particularly desired for some purpose). Proper mold design takes this account and provides sufficient support surface for the flap from the second side of the substrate to maintain it secured during the molding phase. Accordingly, the cuts shall be executed carefully, with necessary accuracy and preferably using relatively sharp blade, laser cutter or other fine precision cutting tool/technique so that the cut lines defining the outline of the flap do not let molten plastic through during the molding.

Obtaining the partially loose portion of the substrate film to create the conductive connector flap may involve introducing a number of cut lines that are cut substantially completely through the substrate so that a flap form is established. Considering e.g. a rectangular planar flap, three edges thereof may be cut completely while the remaining fourth edge shall be left at least partially uncut (perforated, blind cut, etc.) so that the conductors on the first side (molded plastics side) thereof remain intact to provide the electrical connection to the rest of the circuit on the substrate via the flap.

Alternatively or additionally, complete (through) cuts or cut lines may be selectively also more generally replaced with blind cuts or e.g. perforated portions that may still generally follow and define the shape of the connector flap.

A number of electronic components may be provided, by printing and/or mounting, for example, on the first side of the substrate film to establish the desired circuit thereon, which may have control, measurement, UI, data processing, storage, etc. purpose.

Optionally a further, second film may be provided on the other side of the molded plastic as mentioned hereinbefore. It may be located in a mold as well together with the primary first substrate carrying the flap so that a stacked structure is obtained by injecting the plastic material in between, or the second film may be provided afterwards using a suitable lamination technique if not being directly manufactured on the molded plastic layer. The second film may have electronics on any side thereof as well as e.g. graphics (application of IMD/IML technique thus possible). Yet, it may have a protective purpose and/or other technical features such as desired optical transmittance, appearance (e.g. color) or feel.

The feasible molding methods include e.g. injection molding. In case of several plastic materials, they may be molded using a two-shot or generally multi-shot molding method. A molding machine with multiple molding units may be utilized. Alternatively, multiple machines or a single re-configurable machine could be used for sequentially providing several materials.

The previously presented considerations concerning the various embodiments of the structure may be flexibly applied to the embodiments of the method mutatis mutandis, and vice versa, as being appreciated by a skilled person.

The utility of the present invention arises from a plurality of issues depending on the embodiment.

An integral, electrical connector may be conveniently established from a desired portion of the overall substrate film. Complex and space-consuming separate connector elements with own dedicated housing or e.g. a rigid circuit board may be omitted. The location of the connector flap may be flexibly determined and there's no need to position the connectors at the lateral edges of a multilayer structure anymore, which greatly adds to the structural and potentially also functional versatility of the structure and host devices or products they may be disposed at. The connector is bendable/flexible and requires only little space, which facilitates connecting external elements such as connectors or wiring therewith as their initial location is not that critical anymore. Opening or closing the connector flap is a breeze and can be executed by hand (fingernails) or using suitable tools/machinery having suction or other type of picking head, e.g. a sharp blade. The suggested manufacturing method applying overmolding is relatively straightforward and what is considered really beneficial, does not necessitate adopting completely new or different manufacturing technologies just for producing the sufficient connectivity in the context of printed and in-mold electronics.

Similar connector structure may also find use in other scenarios wherein the electrical connection is potentially unnecessary, but e.g. optical connection is desired. Instead or in addition to electrical traces, the connecting elements on the flap may comprise e.g. optical fiber.

Generally, the obtained multilayer structure may be used to establish a desired device or module in a host element such as an intelligent garment (e.g. shirt, jacket, or trousers, or e.g. a compression garment), other piece of wearable electronics (e.g. wristop device, headwear, or footwear), vehicle, personal communications device (e.g. smartphone, phablet or tablet) or other electronics. The integration level of the obtained structure may be high and desired dimensions such as the thickness thereof small.

The used film(s) may contain graphics and other visually and/or tactilely detectable features thereon, whereupon the film may have aesthetic and/or informative effect in addition to hosting and protecting the electronics. The film(s) may be translucent or opaque at least in places. They may be of desired color or comprise portions of desired color. The obtained multilayer structure may thus incorporate one or more color/colored layers that optionally determine graphics such as text, pictures, symbols, patterns, etc. These layers may be implemented by dedicated films of certain color(s), for instance, or provided as coatings (e.g. through printing) on existing film(s), molded layer(s), and/or other surfaces.

The various film(s) of the multiplayer structure may be configured to establish at least a portion of outer and/or inner surface of the associated product.

The visual features such as patterns or coloring may be provided via internal layer(s), e.g. on the side of the first and/or second film that is facing the molded plastics so that the features remain isolated and thus protected from the environmental effects at least by the thickness of the film. Accordingly, different impacts, rubbing, chemicals, etc. that could easily damage e.g. painted surface features do not normally reach them. The film(s) may be easily manufactured or processed, optionally cut, into a desired shape with necessary characteristics such as holes or notches for exposing the underlying features such as the molded material.

The molded thermoplastic material(s) may be optimized for various purposes including securing electronics in view of the molding process. Yet, the material may be configured to protect the electronics from e.g. environmental conditions such as moisture, heat, cold, dirt, shocks, etc. It may further have desired properties in view of light transmittance and/or elasticity, for example. In case the embedded electronics includes light- or other radiation-emitting or receiving components, the material may have sufficient transmittance to enable light transmission therethrough.

The expression “a number of” may herein refer to any positive integer starting from one (1).

The expression “a plurality of” may refer to any positive integer starting from two (2), respectively.

The terms “first” and “second” are herein used to distinguish one element from other element, and not to specially prioritize or order them, if not otherwise explicitly stated.

The terms “film” and “foil” are herein used generally interchangeably, unless otherwise explicitly indicated.

Different embodiments of the present invention are disclosed in the attached dependent claims.

### BRIEF DESCRIPTION OF THE DRAWINGS

Next the present invention will be described in greater detail with reference to the accompanying drawings, in which:

FIG. 1 illustrates one embodiment of a multilayer structure in accordance with the present invention.

FIG. 2 illustrates the embodiment of FIG. 1 with the connector flap, or ‘tail’, shown bent away from the molded plastics.

FIG. 3 illustrates a bottom view of the embodiment of the multilayer structure of FIGS. 1 and 2 with the connector flap correspondingly shown from another perspective.

FIG. 4 is a flow diagram disclosing an embodiment of a method in accordance with the present invention.

### DETAILED DESCRIPTION

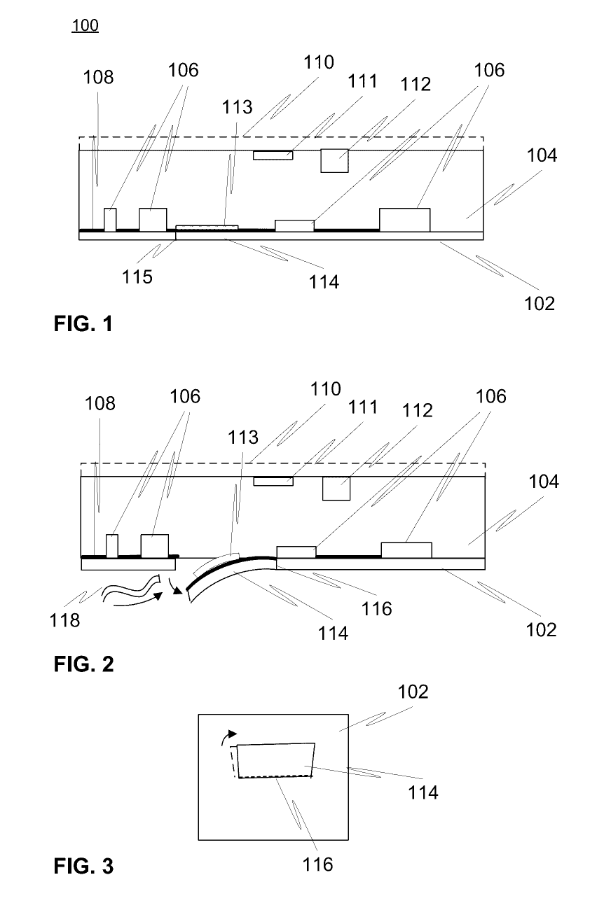

FIG. 1 illustrates, via a cross-sectional side view, an embodiment 100 of a created multilayer structure, which may establish an end product of its own, e.g. electronic device or element (e.g. cable, connector device), or be disposed in a host device as an aggregate part or module. The structure 100 comprises a (first) substrate film 102 such as flexible plastic film to accommodate electronics, such as traces (defining e.g. conductor lines, contact pads, etc.) 108 and optionally components 106, printed on a first side and respective surface thereof by means of printed electronics technology, such as screen printing, flexography or ink jetting. The printed elements incorporating at least the traces are configured so as to establish a desired circuit design. In addition to or instead of printed versions, the components may include ready-made components (surface-) mounted on the substrate 102, such as so-called surface-mounted elements. For example, adhesive may be utilized for mechanically securing the electronics 508 on the substrate. Conductive materials such as conductive adhesive and/or solder may be applied for establishing electrical and also mechanical connections.

The substrate 102 and electronics 106, 108 are at least partially covered by at least one molded plastic layer 104.

An optional second film 110 of same or different material with the first film 102 may be present in the multilayer stack as well. The film 110 may accommodate electronics 112, graphics 111 and/or other features considered advantageous. Further film, coating, etc. may be optionally provided on the second film 110 e.g. for aesthetic, protective/insulating or other purposes.

A connector flap 114 is established by cutting the substrate 102, for example, by means of a laser cutter or a mechanical substrate cutter to partially loose a portion thereof. Cutting may be done prior to or after the molding as explained herein. The cut(s) 115 may be complete, e.g. cut lines going all the way or at least substantially through the thickness of the substrate material along their whole length, and/or e.g. perforated having uncut areas in between. The connector flap 114 may appear as a rectangular or rounded strip, for instance.

The flap 114 may be bent away from the rest of the substrate 102 and molded plastics 104 to expose the conductive portion(s) thereof on the first side to enable establishing the necessary electrical connection between external devices/elements, e.g. wiring or connector, and the circuit within the multilayer stack 100. The electrical connection may serve for the transfer of control information, other data, and/or electrical power, for instance. The flap 114 may bend gradually or comprise a fold and substantially straight adjacent portion.

Material/element 113 that is non-adherent to the molded layer 104 may be provided on the first side of the substrate 102. It 113 may comprise polyimide adhesive tape, non-adherent coating or e.g. especially non-adhering printing material. The use of such material/element 113 is advantageous in a sense that it facilitates detaching and opening the cut portion of the flap 114 by suitable bending, rotating and/or pulling action from the surrounding substrate 102 and especially from the molded plastics 104. The material/ element 113 may cover at least part of the surface of the flap 114 facing the plastic layer 104, or it 113 may cover the flap area on the first side substantially completely. In some embodiments, the material/element 113 may cover even broader area(s) at least on the first side.

Alternatively, the first side of the substrate 102 may be generally provided with material such as a layer of suitable primer that enhances its adherence to the molded layer 104. In this case, the surface area corresponding to the flap 114 on the first side of the substrate 102 may be left without the primer so that the flap 114 may be conveniently opened without excessive, potentially rupturing, force even after molding.

FIG. 2 illustrates such situation where the loose end of the flap 114 has been bent away from the level of the remaining substrate 102 and the plastics 104, thus exposing the conductive portions on the first (i.e. plastics and electronics) side thereof for establishing the electrical contact with external element 118.

The interface region 116 between the flap 114 and the rest of the substrate 102 may be optionally provided with a fold feature (implemented e.g. by a blind (non-through) cut and/or perforation) that facilitates pulling the remote end of the flap from the substrate surface cleanly such that the fold area acts as a joint or hinge.

Use of non-adherent material element 113 is not necessary in situations wherein the substrate 102 (or elements such as traces 108 on the substrate 102) and the plastic layer 104 are at least locally (regarding the flap area) attached to each other so lightly that their separation upon pulling the flap 114 does not damage the concerned interfacing surfaces excessively. As explained hereinbefore, actually the use of a primer to effectively bond a number of desired other areas of the substrate 102 with the plastic layer 104 may be required.

FIG. 3 depicts the substrate 102 when inspected from a direction opposite to the molded layer 104, i.e. via a planar ‘bottom-up’ view. The connector flap 114 may be of rectangular (shown), rounded or basically any other generally applicable shape.

Having regard to the material selections, the film(s) 102, 110 may substantially consist of or comprise at least one material selected from the group consisting of: polymer, thermoplastic material, PMMA (Polymethyl methacrylate), Poly Carbonate (PC), polyimide, a copolymer of Methyl Methacrylate and Styrene (MS resin), glass, Polyethylene Terephthalate (PET), and metal.

In some embodiments, the film(s) 102, 110 may include or be coated or covered by further materials/material layers e.g. on the side facing the environment (i.e. not the electronics 106, 108, 112 and molded material 104). E.g. textile or biological or bio-based materials (e.g. leather, wood, paper, cardboard) in addition to or instead of more conventional layers may be provided. Also e.g. rubber or generally rubberous material may be used. Such layers may have different functionalities, such as a protective function, characterizing desired feel, aesthetic or particular desired light transmissive and/or reflective function and/or indicative function.

The plastic layer(s) 104, provided by the overmolding procedure, may generally incorporate e.g. elastomeric resin. In more detail, the layer(s) 104 may include one or more thermoplastic materials that include at least one material selected from the group consisting of: PC, PMMA, ABS, PET, nylon (PA, polyamide), polypropylene (PP), polystyrene (GPPS), and MS resin.

The electronics 106, 112 may include one or more components, such as passive components, active components, ICs (integrated circuit), and/or sub-assemblies (one or more components first provided on a separate substrate, subsequently attached as a whole to the target substrate 102, 110).

In more detail, the electronics 106, 112 may include at least one element selected from the group consisting of: optoelectronic component, microcontroller, microprocessor, signal processor, DSP (digital signal processor), sensor, programmable logic chip, memory, transistor, resistor, capacitor, inductor, memory array, memory chip, data interface, transceiver, wireless transceiver, transmitter, receiver, wireless transmitter, and wireless receiver.

Still, the electronic components carried by the structure may include at least one optoelectronic component. The at least one optoelectronic component may include a LED (light-emitting diode), an OLED (organic LED), or some other light-emitting component, for example. The components may be side-emitting (‘side shooting’). Alternatively or additionally, it may include light-receiving or light-sensitive component such as a photodiode, photoresistor, other photodetector, or e.g. a photovoltaic cell. The optoelectronic component such as OLED may have been printed on the substrate film using a preferred method of printed electronics technology.

Indeed, e.g. different sensing and/or other functionalities may be implemented by the embedded ICs, dedicated components, or shared ICs/electronics (multi-purpose electronics).

The film(s) 102, 110 may be shaped according to the requirements set by each use scenario. They 102, 110 may exhibit e.g. a rectangular, circular, or square general shape. They 102, 110 may further contain recesses, notches, cuts or openings for various purposes such as attachment to other elements, fitting electronics or other components, provision of passages for light or other radiation, fluid, etc.

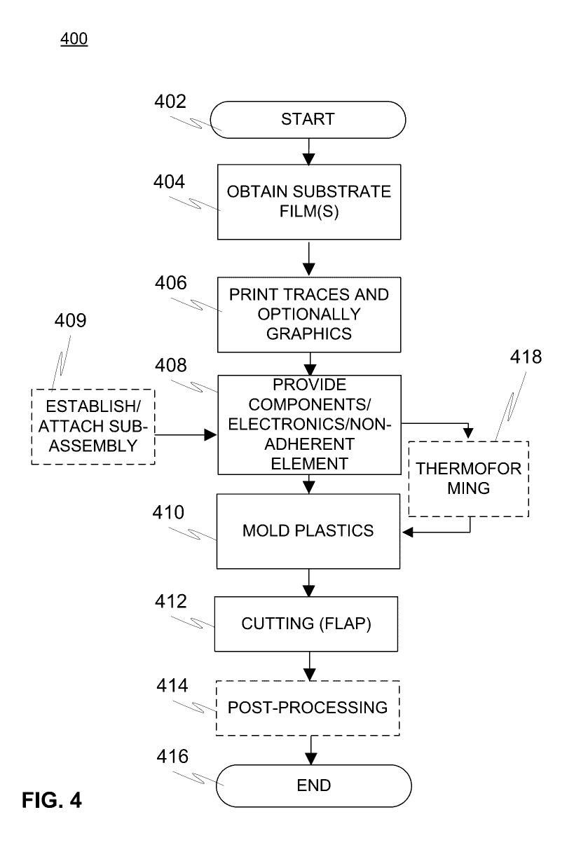

FIG. 4 includes a flow diagram 400 disclosing an embodiment of a method in accordance with the present invention.

At the beginning of the method for manufacturing the multilayer structure, a start-up phase 402 may be executed. During start-up 402, the necessary tasks such as material, component and tools selection, acquisition, calibration and other configuration may take place. Specific care must be taken that the individual elements and material selections work together and survive the selected manufacturing and installation process, which is naturally preferably checked up-front on the basis of the manufacturing process specifications and component data sheets, or by investigating and testing the produced prototypes, for example. The used equipment such as molding/IMD (in-mold decoration), lamination, bonding, thermoforming, cutting, drilling and/or printing equipment, among others, may be thus ramped up to operational status at this stage.

At 404, at least one, preferably flexible, substrate film or other preferably planar substrate for accommodating electronics is obtained. A ready-made element of substrate material, e.g. roll of plastic film, may be acquired. In some embodiments the substrate film itself may be first produced in-house by molding or other methods from the desired starting material(s). Optionally, the substrate film is processed. It may be, for example, provided with openings, notches, recesses, cuts, etc. as contemplated hereinbefore.

At 406, a number of conductive traces defining e.g. conductor lines, contact pads (or other contact areas), etc. for electrically coupling electronic components, are provided on the film(s), preferably by one or more techniques of printed electronics. For example, screen, inkjet, flexographic, gravure or offset lithographic printing may be utilized. Also further actions cultivating the film(s) involving e.g. printing of graphics, visual indicators, etc. on the film(s) may take place here.

At 408, further electronics and/or material non-adherent to molded plastics may be arranged on the substrate optionally by printing. As mentioned hereinbefore, instead of or even in addition to positioning non-adherent material at the location of the connector flap, the other portions on the first side of the substrate may be provided with primer that in contrast, enhances bonding with the molded plastics, whereas the area of the flap is obviously left free from such material. This applies particularly to scenarios wherein the substrate and molded plastic materials do not naturally laminate together tightly due to molding without the use of the primer.

Ready-made components such as various SMDs may be attached to the contact areas by solder and/or adhesives. Alternatively or additionally, printed electronics technology may be applied to actually manufacture at least part of the components, such as OLEDs, directly onto the film(s).

Item 409 refers to possible attachment of one or more sub-systems or ‘sub-assemblies’ that may incorporate an initially separate, secondary substrate provided with electronics such as IC(s) and/or various components. At least part or all of the electronics of the multilayer structure may be provided to the substrate film(s) via such sub-assembly. Optionally, the sub-assembly may be at least partially overmolded by a protective plastic layer prior to attachment to the main substrate. For example, adhesive, pressure and/or heat may be used for mechanical bonding of the sub-assembly with the primary (host) substrate. Solder, wiring and conductive ink are examples of applicable options for providing the electrical connections between the elements of the sub-assembly and with the remaining electrical elements on the primary substrate.

In some embodiments, prior to or upon the molding phase the substrate film(s) optionally already containing electronics may be thermoformed 418. The substrate containing thermoformable material may be shaped to better fit the target environment/device or target use. Additionally or alternatively, thermoforming could take place after molding in case the already-established multilayer stack is designed to survive such processing.

At 410, thermoplastic layer is molded upon the first side of the substrate film and electronics thereon, such as traces and a number of electronic components. In practice, the substrate film may be used as an insert in an injection molding process. The first side and associated surface of the substrate element may be, in some embodiments, left with one or more areas free from the molded plastics.

In case, two films are used, both of them may be inserted in their own mold halves so that the plastic layer is injected between them. Alternatively, the second film could be attached to an aggregate of first film and plastic layer afterwards by suitable lamination technique.

Regarding the resulting overall thickness of the obtained stacked structure, it heavily depends on the used materials and related minimum material thicknesses providing the necessary strength in view of the manufacturing and subsequent use. These aspects have to be considered on case-by-case basis. For example, the overall thickness of the structure could be about 1 mm, but considerably thicker or thinner embodiments are also feasible.

At 412, the connector flap is formed by cutting the primary substrate material as discussed hereinbefore. The execution order of items 410 and 412 may be reversed depending on the embodiment.

Item 414 refers to possible post-processing tasks. Further layers may be added into the multilayer structure by lamination or suitable coating (e.g. deposition) procedure. The layers may be of indicative or aesthetic value and contain e.g. textile, leather or rubber materials instead of or in addition to further plastics. Additional elements such as electronics may be installed at the outer surface(s) of the structure, such as the exterior surface of the substrate. Shaping/cutting may take place.

The flap may be bent away from the level of the remaining substrate and molded plastics for connecting it (via the exposed first surface) with an external element such as electrical wiring, cable or connector.

At 416, method execution is ended.

The scope of the present invention is determined by the attached claims together with the equivalents thereof. A person skilled in the art will appreciate the fact that the disclosed embodiments were constructed for illustrative purposes only, and other arrangements applying many of the above principles could be readily prepared to best suit each potential use scenario. For instance, instead of or in addition to molding the plastics directly onto the substrate, the plastic layer could be prepared upfront and then attached to the substrate by suitable lamination technique applying e.g. adhesive, mechanical attachment means (screws, bolts, nails, etc.), pressure and/or heat. Finally, in some scenarios, instead of molding, the plastic or other layer of similar function could be produced on the substrate using a suitable deposition or further alternative method. Yet, instead of printed traces, the traces could be produced/provided otherwise. E.g. a conductor film manufactured utilizing etching, for example, could be applied.

1. A multilayer structure (100), comprising
a preferably flexible substrate film (102) having a first side and opposite second side,
a number of conductive traces (108), optionally defining contact pads and/or conductors, preferably printed on the first side of the substrate film by printed electronics technology for establishing a desired predetermined circuit design,
a plastic layer (104) molded onto the first side of the substrate film (102) so as to enclose the circuit between the plastic layer and the first side of the substrate film (102), and
a connector (114) in a form of a preferably flexible flap for providing external electrical connection to the embedded circuit from the second, opposite side of the substrate film (102),
the connector being defined by a portion of the substrate film accommodating at least part of one or more of the conductive traces (108) and cut partially loose from the surrounding substrate material so as to establish the flap, the loose end of which is bendable away from the molded plastic layer to facilitate the establishment of said electrical connection with an external element (118), such as a wire or connector, via the associated gap.

2. The structure of claim 1, wherein the substrate film (102) contains, on the first side and substantially at the location of the connector, element or material (113) non-adherent to the molded plastic layer.

3. The structure of claim 1, comprising primer on the first side of the substrate film (102) to strengthen the attachment of the substrate film (102) to the molded plastic layer (104), the areas provided with primer substantially excluding the area of the connector flap (114).

4. The structure of claim 1, comprising a further film (110) on the side of the plastic layer (104) facing away from the substrate film (102), optionally accommodating graphics (111) and/or electronics (112) thereon.

5. The structure of claim 1, comprising a fold at the interface region (116) of the connector flap (114) and the rest of the substrate film (102).

6. The structure of claim 1, wherein the fold incorporates a blind cut or perforation.

7. The structure of claim 1, comprising one or more embedded color or graphical layers preferably exhibiting a desired color, figure, graphical pattern, symbol, text, numeric, alphanumeric and/or other visual indication.

8. A method for manufacturing a multilayer structure (100), comprising
obtaining a substrate film (404) for accommodating electronics,
providing, preferably through printing, a number of conductive traces (406), and optionally electronic components (408), on a first side of the substrate film to establish a predetermined circuit design,
molding the thermoplastic material (410) on said first side of the substrate film to substantially seal the circuit between the plastic layer and the first side of the substrate film, and
cutting, from the substrate film, optionally excluding the periphery of the film, a partially loose flap portion (412) comprising conductive region facing the molded material and preferably accommodating at least part of one or more of the traces.

9. The method of claim 8, further comprising providing a separator material or element substantially non-adherent (408) to thermoplastic material to be molded on the first side of the substrate.

10. The method of claim 9, wherein the separator material is provided to a predefined location of a connector flap on the first side.

11. The method of claim 8, further comprising bending the loose connector flap portion away from the molded plastic layer and the level of the remaining substrate film to enable an external element, optionally a wire or a connector, to contact the conductive region of the flap from a second, opposite side of the substrate film via the established gap.

12. The method of claim 9, further comprising bending the loose connector flap portion away from the molded plastic layer and the level of the remaining substrate film to enable an external element, optionally a wire or a connector, to contact the conductive region of the flap from a second, opposite side of the substrate film via the established gap.

13. The method of claim 10, further comprising bending the loose connector flap portion away from the molded plastic layer and the level of the remaining substrate film to enable an external element, optionally a wire or a connector, to contact the conductive region of the flap from a second, opposite side of the substrate film via the established gap.
